(19) United States
(12) Patent Application Publication
(10) Pub. No.: US 2011/0263117 A1
(43) Pub. Date: Oct. 27, 2011

(54) APPARATUS FOR MANUFACTURING SEMICONDUCTOR DEVICE AND METHOD OF MANUFACTURING SEMICONDUCTOR DEVICE USING THE SAME

(75) Inventors: Sang-Don Nam, Seoul (KR); Sang-Hoon Ahn, Hwaseong-si (KR); Byung-Hee Kim, Seoul (KR); Kyu-Hee Han, Hwaseong-si (KR)

(73) Assignee: SAMSUNG ELECTRONICS CO., LTD., SUWON-SI (KR)

(21) Appl. No.: 13/094,342

(22) Filed: Apr. 26, 2011

(30) Foreign Application Priority Data
Apr. 27, 2010 (KR) 10-2010-0039089

(51) Int. Cl. H01L 21/768; H01L 21/28

(52) U.S. Cl. 438/627; 438/618; 257/E21.584; 257/E21.158

(57) ABSTRACT

A method of manufacturing a semiconductor device and an apparatus for manufacturing a semiconductor device in which moisture is removed from a porous low-dielectric layer after a chemical mechanical polishing (CMP) process include formation of a porous low-dielectric layer on a substrate. A metal interconnection is formed on the substrate having the porous low-dielectric layer. The metal interconnection forms a planar surface with the porous low-dielectric layer to fill the openings. Ultraviolet (UV) light is irradiated to the porous low-dielectric layer to remove absorbed moisture from the porous low-dielectric layer. A capping layer is formed on the substrate having the porous low-dielectric layer and the metal interconnection. The capping layer is formed in-situ to prevent additional absorption of moisture.

### CROSS-REFERENCE TO RELATED APPLICATION

This application claims priority under 35 U.S.C. §119 to Korean Patent Application No. 10-2010-0039089 filed in the Korean Intellectual Property Office on Apr. 27, 2010, the entire contents of which are hereby incorporated by reference.

### BACKGROUND

1. Field

Embodiments of the inventive concept relate to a method of manufacturing a semiconductor device having a porous low-dielectric layer and a metal interconnection disposed in the porous low-dielectric layer. Embodiments of the inventive concept also relate to an apparatus for manufacturing the semiconductor device.

2. Description of Related Art

With the increase in the integration density of semiconductor devices, the distance between interconnections has gradually decreased. Thus, metal interconnections need to include a low-resistance conductive material, and insulating layers need to include a low-dielectric material to reduce resistance-capacitance (RC) delay.

Conventionally, after a portion of an insulating layer is etched and filled with a conductive material, the conductive material may be polished. During the polishing process, since the insulating layer is exposed to the air, the metal interconnections may be oxidized, and moisture may be absorbed into the insulating layer. The oxidation of the metal interconnections may accelerate electromigration (EM), and the moisture absorbed in the insulating layer may increase the dielectric constant of the insulating layer and degrade time-dependent dielectric breakdown (TDDB) characteristics.

### SUMMARY

Embodiments of the inventive concept provide a method of manufacturing a semiconductor device in which moisture contained in a porous low-dielectric layer can be removed during formation of a metal interconnection to improve electrical properties.

Also, embodiments of the inventive concept provide an apparatus for manufacturing a semiconductor device, by which moisture contained in a porous low-dielectric layer can be removed during formation of a metal interconnection to improve electrical properties.

In accordance with an aspect of the inventive concept, a method of manufacturing a semiconductor device includes forming a porous low-dielectric layer on a substrate. A metal interconnection is formed on the substrate having the porous low-dielectric layer. Ultraviolet (UV) light having a wavelength of 260 to 450 nm is irradiated to the porous low-dielectric layer. A capping layer is formed on the substrate having the porous low-dielectric layer and the metal interconnection.

The porous low-dielectric layer may include a material selected from the group consisting of a SiOCH layer, a SiOC layer, and a SiOF layer. The porous low-dielectric layer may have a dielectric constant of about 1 to 2.5.

The capping layer may include a material selected from the group consisting of a SiN layer, a SiCN layer, a BN layer, a BCN layer, and a mixture thereof. The metal interconnection may include copper (Cu) or a Cu alloy.

The irradiation of UV light to the porous low-dielectric layer and the formation of the capping layer on the substrate may be performed in-situ.

The formation of the porous low-dielectric layer may include forming a low-dielectric layer including a pore generator (or porogen) on the substrate and removing the porogen.

The removal of the porogen may be performed using at least one of a UV irradiation process, an electronic beam (e-beam) irradiation process, and an annealing process.

The formation of the metal interconnection may include etching a portion of the porous low-dielectric layer to form an opening. A barrier layer may be formed to cover the opening and the porous low-dielectric layer. A metal layer may be formed on the barrier layer to fill the opening. A portion of the metal layer and the barrier layer formed on the porous low-dielectric layer may be polished to expose a top surface of the porous low-dielectric layer.

The polishing of the metal layer and the barrier layer formed on the porous low-dielectric layer may include performing a chemical mechanical polishing (CMP) process using the top surface of the porous low-dielectric layer as an etch stopper.

The barrier layer may include at least one material selected from the group consisting of titanium (Ti), tantalum (Ta), tungsten (W), and a nitride thereof.

After irradiating UV light to the porous low-dielectric layer and before forming the capping layer, the method may further include processing the porous low-dielectric layer and the metal interconnection using plasma. The irradiation of UV light to the porous low-dielectric layer, the processing of the porous low-dielectric layer and the metal interconnection using plasma, and the formation of the capping layer on the substrate may be performed in-situ.

The processing of the porous low-dielectric layer and the metal interconnection using plasma may be performed in an atmosphere containing at least one of ammonia (NH₃), hydrogen (H₂), helium (He), nitrogen (N₂), argon (Ar), and a mixture thereof.

In accordance with another aspect of the inventive concept, an apparatus for manufacturing a semiconductor device includes: a UV irradiation chamber and a capping layer deposition chamber. The UV irradiation chamber may irradiate UV light having a wavelength of about 260 to 450 nm. The capping layer deposition chamber may be disposed adjacent to the UV irradiation chamber and include a capping layer depositor. Processes performed in the UV irradiation chamber and the capping layer deposition chamber may be performed in-situ.

The apparatus may further include a plasma process chamber interposed between the UV irradiation chamber and the capping layer deposition chamber. The plasma process chamber may include a plasma generator. Processes performed in the UV irradiation chamber, the capping layer deposition chamber, and the plasma process chamber may be performed in-situ. The plasma process chamber performs a plasma process in an atmosphere containing at least one of NH₃, H₂, He, N₂, Ar, and a mixture thereof

The UV irradiation chamber may include: a UV lamp configured to irradiate UV light having a wavelength of about 260 to 450 nm, or a wide-bandgap UV lamp and a UV filter configured to selectively transmit UV light having a wavelength of about 260 to 450 nm.

The capping layer deposition chamber may perform one process selected from the group consisting of a plasma-enhanced chemical vapor deposition (PECVD) process, a thermal CVD process, a CVD process, a spin coating process, a sputtering deposition process, a physical vapor deposition (PVD) process, and an atomic layer deposition (ALD) process. The capping layer deposition chamber may form at least one layer selected from a SiN layer, a SiCN layer, a BN layer, and a BCN layer.

The apparatus may further include a transfer module and a loadlock chamber. The transfer module may be disposed adjacent to one side of the UV irradiation chamber and the capping layer deposition chamber. The loadlock chamber may be disposed adjacent to the transfer module and may be configured to receive a substrate to be transferred to the transfer module.

In accordance with another aspect of the inventive concept, an apparatus for manufacturing a semiconductor device includes: an ultraviolet (UV) irradiation chamber configured to irradiate UV light having a wavelength of about 260 to 450 nm; a capping layer deposition chamber disposed adjacent to the UV irradiation chamber and including a capping layer depositor; a plasma process chamber interposed between the UV irradiation chamber and the capping layer deposition chamber and including a plasma generator; a transfer module disposed adjacent to one side of the UV irradiation chamber and the capping layer deposition chamber; and a loadlock chamber disposed adjacent to the transfer module and configured to receive a substrate to be transferred to the transfer module. Processes performed in the UV irradiation chamber, the capping layer deposition chamber, and the plasma process chamber are performed in-situ.

The plasma process chamber may perform a plasma process in an atmosphere containing at least one of NH₃, H₂, He, N₂, Ar, and a mixture thereof.

The UV irradiation chamber may include at least one of a UV lamp configured to irradiate UV light having a wavelength of about 260 to 450 nm, and a wide-bandgap UV lamp and a UV filter configured to selectively transmit UV light having a wavelength of about 260 to 450 nm.

The capping layer deposition chamber may perform a plasma-enhanced chemical vapor deposition (PECVD) process, a thermal CVD process, a CVD process, a spin coating process, a sputtering deposition process, a physical vapor deposition (PVD) process, and/or an atomic layer deposition (ALD) process.

The capping layer deposition chamber forms at least one layer selected from a SiN layer, a SiCN layer, a BN layer, and a BCN layer.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts.

FIG. 1 is a flowchart illustrating a method of manufacturing a semiconductor device according to embodiments of the inventive concept.

FIGS. 2A through 2J are schematic cross-sectional views illustrating a method of manufacturing a semiconductor device according to embodiments of the inventive concept.

FIG. 3 is a graph showing comparison in Fourier transform infrared (FTIR) spectrum between a case in which moisture is removed from a porous low-dielectric layer using UV light and a case in which UV light is not irradiated.

FIG. 4 is a transmission electron microscopy (TEM) image of a section of a metal interconnection and a porous low-dielectric layer when UV light having a wavelength of about 200 nm is irradiated.

FIGS. 5 and 6 are schematic views of an apparatus for manufacturing a semiconductor device according to embodiments of the inventive concept.

### DETAILED DESCRIPTION OF THE EMBODIMENTS

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this description is thorough and complete and fully conveys the inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

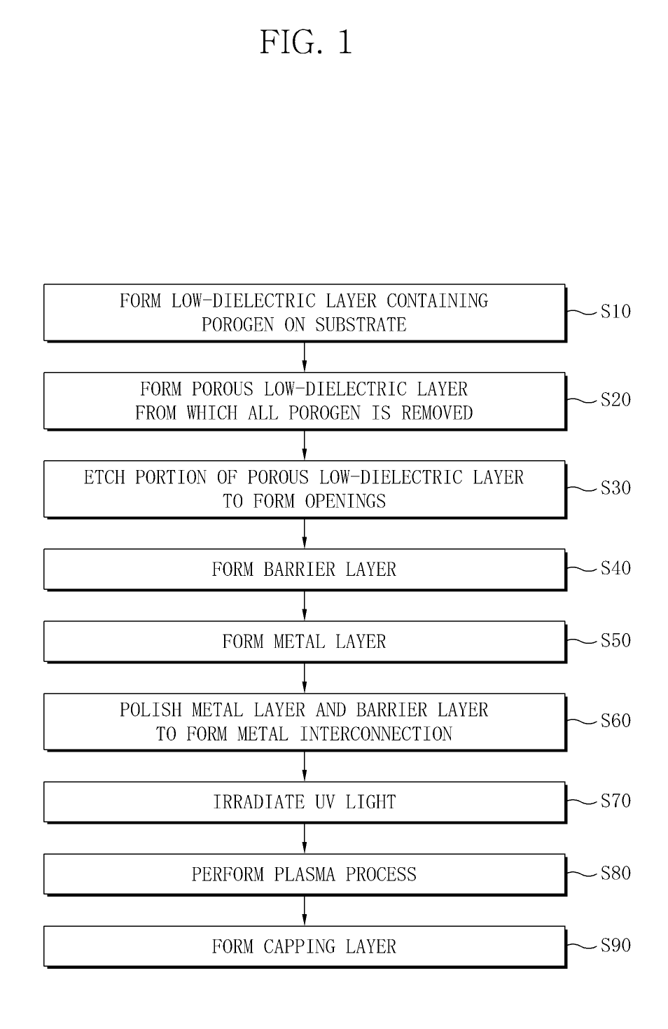

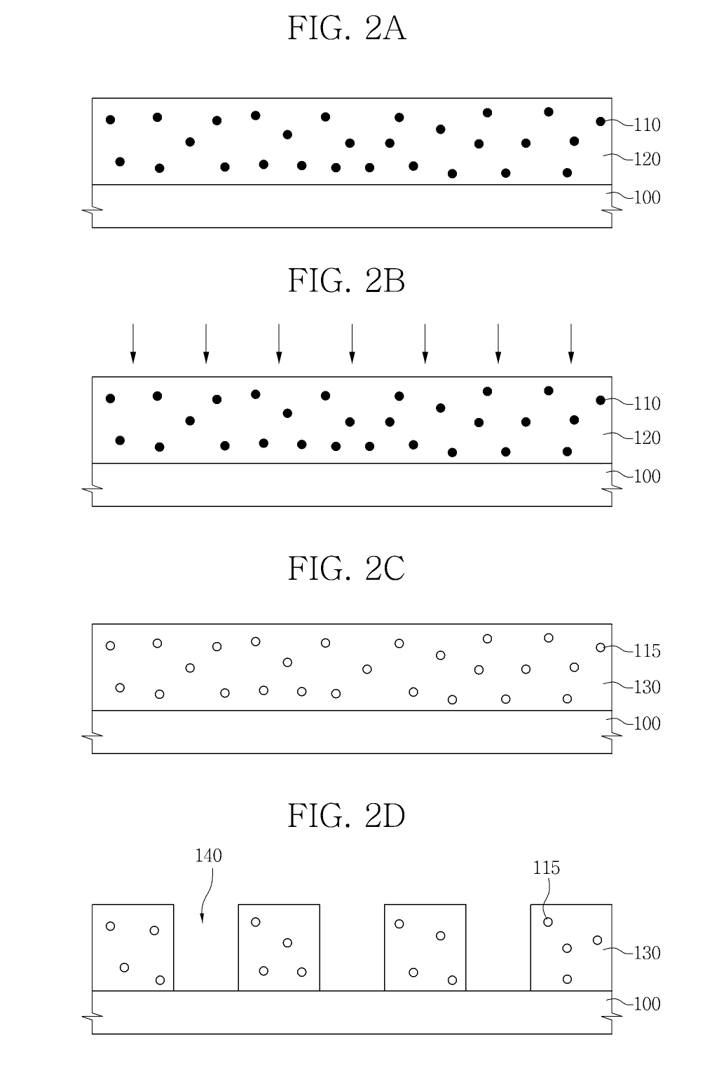

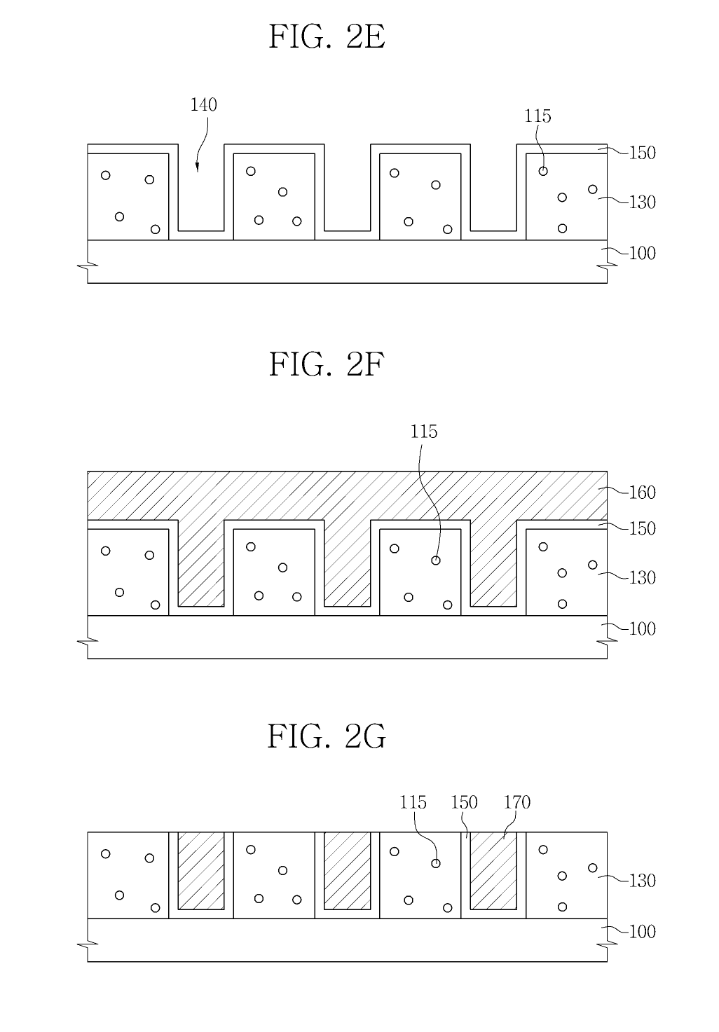

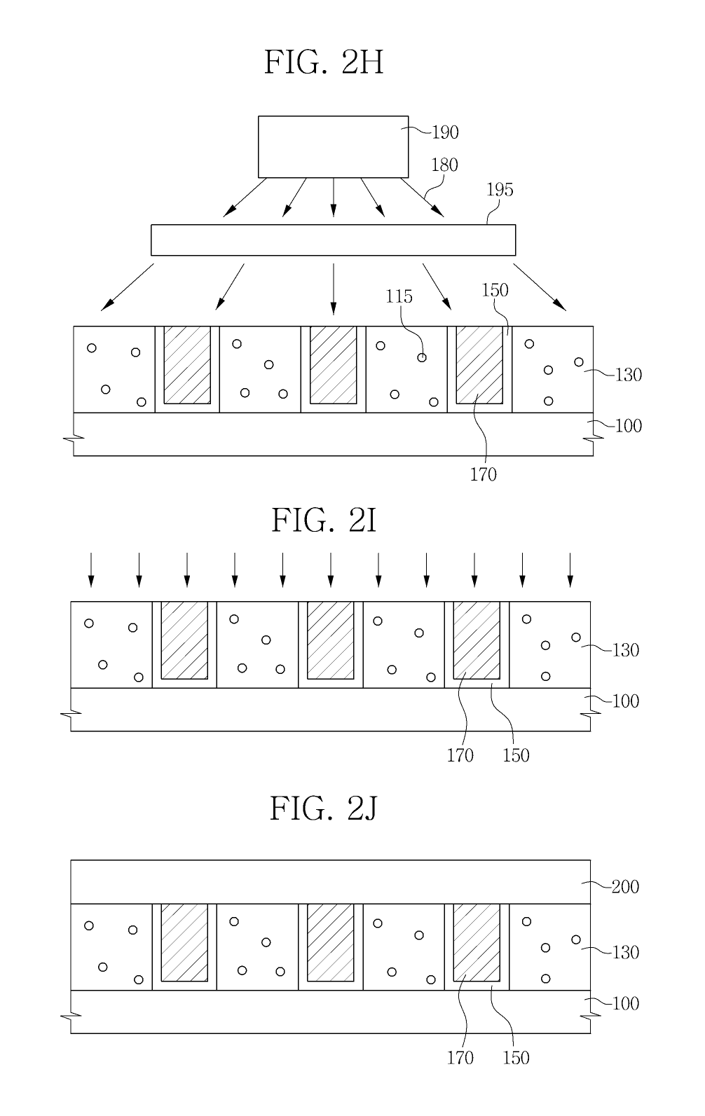

Hereinafter, a method of manufacturing a semiconductor device according to embodiments of the inventive concept will be described with reference to FIGS. 1 and 2A through 2J. FIG. 1 is a flowchart illustrating a method of manufacturing a semiconductor device according to embodiments of the inventive concept, and FIGS. 2A through 2J are schematic cross-sectional views illustrating a method of manufacturing a semiconductor device according to embodiments of the inventive concept.

Referring to FIGS. 1 and 2A, a low-dielectric layer 120, i.e., a layer having relatively low dielectric constant, including a pore generator (hereinafter, referred to as a “porogen”) 110 may be formed on a substrate 100 (operation S10). The low-dielectric layer 120 may be formed, for example, using a chemical vapor deposition (CVD) process or a spin coating process. To reduce a resistance-capacitance (RC) delay, the low-dielectric layer 120 may include a low-dielectric material having a lower dielectric constant than a basic oxide or nitride material layer. The low-dielectric layer 120 may include a material selected from the group consisting of a SiOCH layer, a SiOC layer, and a SiOF layer including the porogen 110, but the inventive concept is not limited thereto. The low-dielectric layer 120 may include the porogen 110, which is uniformly distributed in the low-dielectric layer 120. Since pores are formed by removing the porogen 110, the dielectric constant of the low-dielectric layer 120 may be further reduced.

The substrate 100 may be a rigid substrate or a flexible plastic substrate. The rigid substrate may be a semiconductor substrate, a silicon-on-insulator (SOI) substrate, a quartz substrate, a rigid substrate, or a display glass substrate. The semiconductor substrate may include at least one semiconductor material selected from the group consisting of Si, Ge, SiGe, GaP, GaAs, SiC, SiGeC, InAs, and InP. The flexible plastic substrate may include a material selected from the group consisting of polyimide, polyethylene terephthalate (PET), polyethylene naphthalate (PEN), polymethyl methacrylate (PMMA), polycarbonate (PC), polyethersulfone (PES), and polyester.

Forming the low-dielectric layer 120 on the substrate 100 may not refer to forming the low-dielectric layer 120 directly on the substrate 100. For example, a plurality of conductive layers, a plurality of dielectric layers, and/or a plurality of insulating layers may be formed between the substrate 100 and the low-dielectric layer 120. For the sake of clarity, an example case in which the low-dielectric layer 120 is formed directly on the substrate 100 according to embodiments of the inventive concept will be described.

Referring to FIGS. 1 and 2B, the porogen 110 of the low-dielectric layer 120 may be removed using a curing process (operation S20). Thus, as shown in FIG. 2C, all the porogen 110 of the low-dielectric layer 120 may be removed, thereby forming a porous low-dielectric layer 130. The process of curing the low-dielectric layer 120 may be performed using at least one of an ultraviolet (UV) irradiation process, an e-beam irradiation process, and an annealing process. That is, any process for applying energy so as to remove the porogen 110 may be used and determined according to the properties and type of porogen 110. The porogen 110 may be wholly removed through the curing process, and pores 115 may be formed in portions of the low-dielectric layer 120 from which the porogen 110 is removed, thus resulting in formation of a porous low-dielectric layer 130 having a lower dielectric constant than the low-dielectric layer 120. The porous low-dielectric layer 130 having the pores 115 may have a dielectric constant of about 1 to 2.5.

Referring to FIGS. 1 and 2D, a portion of the porous low-dielectric layer 130 may be etched, thereby forming a porous low-dielectric layer 130 having openings 140 exposing the substrate 100 (operation S30). According to embodiments of the inventive concept, a photoresist layer (not shown) may be formed on the porous low-dielectric layer 130 and patterned using exposure and development processes to form a photoresist pattern (not shown). An oxide layer exposed by the photoresist pattern may be dry or wet etched, and the photoresist pattern may be removed using ashing and stripping processes. As a result, the openings 140 may be formed in the porous low-dielectric layer 130 to expose the substrate 100.

Referring to FIGS. 1 and 2E, a barrier layer 150 may be formed on inner surfaces of the openings 140 and a top surface of the porous low-dielectric layer 130 (operation S40). The barrier layer 150 may prevent a subsequent metal of metal interconnection from diffusing into the porous low-dielectric layer 130. According to embodiments of the inventive concept, the barrier layer 150 may include at least one material selected from the group consisting of titanium (Ti), tantalum (Ta), tungsten (W), and a nitride thereof. The barrier layer 150 may continuously cover inner walls and bottom surfaces of the openings 140 and a top surface of a portion of the porous low-dielectric layer 130 where no opening 130 is formed.

The barrier layer 150 may be formed using a CVD process, a sputtering deposition process, a physical vapor deposition (PVD) process, an atomic layer deposition (ALD) process, an electronic beam (e-beam) evaporation process, an electroless-chemical deposition process, or an electro-chemical deposition process.

Referring to FIGS. 1 and 2F, a metal layer 160 may be formed on the barrier layer 150 to completely fill the openings 140 (operation S50). The metal layer 160 may be formed to a sufficient thickness to fill the openings 140 and cover the barrier layer 150.

According to embodiments of the inventive concept, the metal layer 160 may include copper (Cu) or a Cu alloy. For example, a Cu seed layer (not shown) may be formed on the barrier layer 150, and a Cu layer may be formed on the Cu seed layer using an electroplating process. The barrier layer 150 may be used as a seed layer for an electroplating process. In this case, the formation of the Cu seed layer may be omitted.

According to other embodiments of the inventive concept, the metal layer 160 may include at least one material selected from the group consisting of aluminum (Al), tungsten (W), rhodium (Rh), osmium (Os), titanium (Ti), tantalum (Ta), palladium (Pd), platinum (Pt), molybdenum (Mo), a metal silicide, and a combination thereof.

Referring to FIGS. 1 and 2G, a portion of the metal layer (refer to 160 in FIG. 2F) and the barrier layer 150 formed on the top surface of the porous low-dielectric layer 130 may be polished, thereby forming a metal interconnection 170 (operation S60). The polishing process may be performed using the porous low-dielectric layer 130 as an etch stopper. As a result, the metal layer 160 and the barrier layer 150 may be planarized, thereby exposing the porous low-dielectric layer 130. Due to the polishing process, the top surface of the porous low-dielectric layer 130 may be exposed, and the metal interconnection 170 may form a planar top surface with the porous low-dielectric layer 130. The metal interconnection 170 may be electrically insulated by the porous low-dielectric layer 130.

The polishing process may be performed using a chemical mechanical polishing (CMP) process or an etchback process. An exemplary process of forming the metal interconnection 170 using a CMP process according to embodiments of the inventive concept are described herein.

Referring to FIGS. 1 and 2H, moisture of the porous low-dielectric layer 130 and the metal layer 160 may be removed by irradiating UV light 180 or e-beams having predetermined energy (operation S70). When the top surface of the porous low-dielectric layer 130 is exposed to the air due to the CMP process, moisture may be absorbed into the porous low-dielectric layer 130. Also, water and slurry may be brought into contact with a wafer during the CMP process. In this case, the water may be absorbed into the porous low-dielectric layer 130.

The absorption of moisture in the porous low-dielectric layer 130 may increase the dielectric constant of the porous low-dielectric layer 130, thereby degrading the electrical properties of the semiconductor device. When a SiOCH layer is used as the porous low-dielectric layer 130 according to embodiments of the inventive concept, H₂O moisture may be directly absorbed into pores 115 formed in the SiOCH layer due to van der Waals force, or the SiOCH layer may absorb moisture in the form of Si—OH bonds or Si—H bonds.

According to embodiments of the inventive concept, when the metal layer 160 includes Cu or a Cu alloy, the metal interconnection 170 including the Cu or Cu alloy may also be exposed to and affected by the air after the CMP process. Since the Cu or Cu alloy is oxidized to form oxidized copper (CuOₓ), the electrical properties of the metal interconnection 170 may be degraded. Although the oxidized copper formed in the metal interconnection 170 is easily removed due to a subsequent plasma process, moisture absorbed in the porous low-dielectric layer 130 may not be easily removed.

After the above-described CMP process, the moisture absorbed in the porous low-dielectric layer 130 may be removed by irradiating UV light having predetermined energy or e-beam light to the top surface of the porous low-dielectric layer 130 or the top surface of the metal interconnection 170.

The following Table 1 shows kinds and energies of bonding of solid Si in the porous low-dielectric layer 130. As described above, after the CMP process, moisture may be absorbed in the SiOCH layer in the form of Si—OH bonds or Si—H bonds.

TABLE 1

| Kind of bonds | Bonding energy (eV) |
|---|---|
| Si—H | 3.39 |
| O—H | 4.44 |
| Si—C | 4.7 |
| Si—OH | 7.89 |
| Si—O | 7.98 |

Hereinafter, the embodiments of the inventive concept will be described on the assumption that UV light is used as light energy. The light energy of UV light 180 irradiated to the top surface of the porous low-dielectric layer 130 and the top surface of the metal interconnection 170 may be lower than energy of Si—C bonds. This is because a break in Si—C bonds may cause a structural change to the SiCOH layer to bring about cross-linking in the SiCOH layer. Due to the cross-linking in the SiCOH layer, the porous low-dielectric layer 130 may shrink and be delaminated from the metal interconnection 170. Thus, UV light 180 having a wavelength of longer than 260 nm, which has energy corresponding to Si—C bonding energy (4.7 eV), may be irradiated.

As shown in Table 1, although UV light having an energy of 7.89 eV, enough to remove —OH functional groups from Si—OH which is one form of absorbed moisture, may be considered to be irradiated, since Si—OH bonds have about the same bonding energy as Si—O bonds, the Si—O bonds can readily be broken. That is, the irradiation of UV light having a short wavelength of about 250 nm or less may lead to changes in the structural and physical properties of the porous low-dielectric layer 130, so that the dielectric properties of the porous low-dielectric layer 130 may be changed to degrade the electrical properties of the porous low-dielectric layer 130.

However, the irradiation of UV light 180 having a wavelength of about 260 nm or more may enable removal of hydrogen (—H) functional groups from Si—OH bonds so that hydroxyl (—OH) functional groups may be reduced from Si—OH which is one form of absorbed moisture without breaking Si—O bonds.

Furthermore, the irradiation of UV light having a wavelength shorter than 260 nm may detrimentally affect not only the porous low-dielectric layer 130 but also the metal interconnection 170. When the metal interconnection 170 includes Cu or a Cu alloy, the irradiation of UV light having a wavelength shorter than 260 nm to the top surface of the porous low-dielectric layer 130 or the top surface of the Cu metal interconnection 170 may cause hillocks on the surface of the Cu metal interconnection 170. Accordingly, when the UV light 180 having a wavelength of 260 nm or more is irradiated, the metal interconnection 170 may maintain good surface characteristics.

When H₂O moisture is absorbed into the pores 115 of the porous low-dielectric layer 130, the H₂O moisture may be attached to inner walls of the pores 115 due to van der Waals force. In this case, the H₂O moisture may be removed more easily with a lower energy than when Si—OH and Si—H absorbed moisture is removed. The UV light 180 having a wavelength of about 450 nm or less may be irradiated to remove the H₂O absorbed moisture.

Thus, according to embodiments of the inventive concept, the UV light 180 having a wavelength of about 260 to 450 nm may be irradiated. In particular, the UV light 180 having a wavelength of about 260 to 280 nm may be irradiated to facilitate removal of —H functional groups from Si—OH bonds. All kinds of absorbed moisture, for example, H₂O absorbed moisture, Si—OH absorbed moisture, and Si—H absorbed moisture, may be removed using one absorbed-moisture removing process.

As long as the UV light 180 has a wavelength of about 260 to 450 nm, light having a longer wavelength may be selectively used. For example, when the UV light 180 irradiated to the top surfaces of the porous low-dielectric layer 130 and the metal interconnection 170 has a wavelength of about 260 nm, the UV light 180 may or may not reach a peak in a wavelength range longer than 260 nm. That is, a peak in the shortest wavelength of the irradiated UV light 180 may range from 260 to 450 nm.

Light irradiated to the top surface of the porous low-dielectric layer 130 and the top surface of the metal interconnection 170 may be irradiated to have such an intensity as to remove —H functional groups from Si—OH bonds or Si—H bonds in the wavelength range of about 260 to 450 nm. Also, when e-beams are used as a light source, the e-beams may have an energy lower than energy corresponding to the wavelength (260 nm) of the UV light 180.

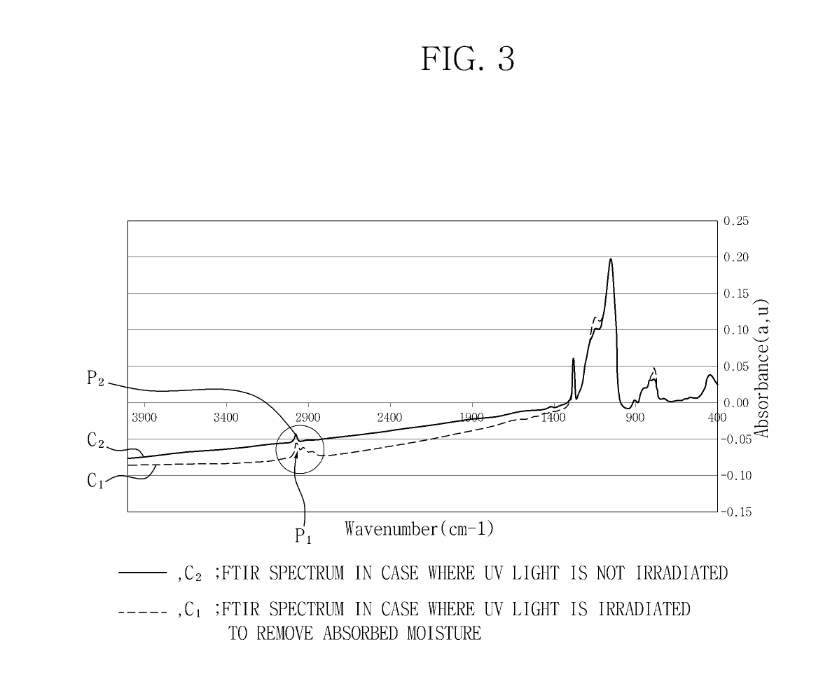

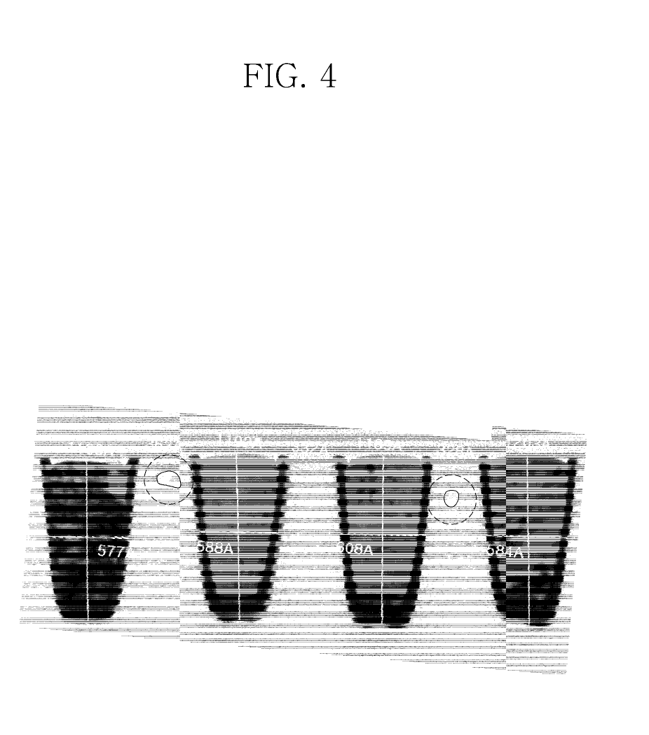

FIG. 3 shows a comparison between a Fourier transform infrared (FTIR) spectrum obtained in a case in which moisture is removed from a porous low-dielectric layer using UV light and an FTIR spectrum obtained in a case in which UV light is not irradiated. Referring to FIG. 3, a dotted spectrum C₁ shows a case in which UV light having a wavelength of about 270 nm is irradiated, while a solid spectrum C₂ shows a case in which UV light is not irradiated. In FIG. 3, an abscissa denotes the wave number of infrared (IR) irradiation, and an ordinate denotes the absorbance of the IR irradiation. A peak of an absorption spectrum of —OH functional groups is about 3000 cm¹. A peak indicated by a fine solid circle is caused by —OH functional groups. As can be seen from FIG. 3, a peak P₁ obtained in a case in which absorbed moisture is removed with UV irradiation is located lower than a peak P₂ obtained in a case in which an absorbed-moisture removing process is omitted. Therefore, it can be concluded that the irradiation of UV light may reduce absorbance caused by —OH functional groups. That is, when an absorbed-moisture removing process is performed by irradiating UV light with a wavelength of about 270 nm, —OH functional groups may be removed by removing —OH and —H functional groups at a higher rate than when the absorbed-moisture removing process is omitted. Accordingly, when UV light having a wavelength of about 270 nm is irradiated to the porous low-dielectric layer 130 after a CMP process, Si—OH absorbed moisture caused by air exposure may be removed very effectively.

FIG. 4 is a transmission electron microscopy (TEM) image of a section of the metal interconnection 170 and the porous low-dielectric layer 130 when UV light having a short wavelength of about 200 nm is irradiated to the porous low-dielectric layer 130 after a CMP process. Referring to FIG. 4, it can be observed that voids are formed in sections illustrated with dotted circles of the porous low-dielectric layer 130. This is because a break in Si—C bonds causes a structural change to the SiCOH layer to bring about cross-linking in the SiCOH layer. The voids may be entirely different in size from the pores 115 of the porous low-dielectric layer 130. The voids may degrade the surface characteristics of the metal interconnection 170, thus causing delamination of the porous low-dielectric layer from the metal interconnection 170. In addition, the formation of the voids may lead to degradation of the electrical properties of the porous low-dielectric layer 130, for example, occurrence of a leakage current.

When absorbed moisture is removed using UV light 180 having a wavelength of about 260 to 450 nm, a UV lamp or both a wide-bandgap UV lamp 190 and a UV filter 195 may be employed. In this case, the UV lamp may be capable of irradiating UV light 180 with a wavelength of about 260 to 450 nm, and the UV filter 195 may be capable of selectively transmitting UV light with a wavelength of about 260 to 450 nm.

Referring to FIGS. 1 and 21, after the absorbed moisture is removed from the porous low-dielectric layer 130, a plasma process may be performed (operation S80). According to embodiments of the inventive concept, the plasma process may be an optional process. When the plasma process is performed, the plasma process and the moisture removing process, such as the UV irradiation process, may be performed in-situ. This is because a break in a vacuum state may result in additional absorption of moisture or formation of a copper oxide (CuOₓ) in the metal interconnection formed of, for example, Cu or a Cu alloy.

A plasma process may be performed on the surface of the metal interconnection 170 to remove a metal oxide layer, which may be formed due to the exposure of the surface of the metal interconnection 170 to the air, using a reduction reaction. The plasma process may greatly reduce the likelihood of hillocks on the surface of the metal interconnection 170. The plasma process may be performed in an atmosphere containing NH₃, H₂, He, N₂, Ar, or a mixture thereof.

Referring to FIGS. 1 and 2J, after the plasma process is performed or after the absorbed moisture removing process is performed without the plasma process, a capping layer 200 may be formed (operation S90). The capping layer 200 may prevent flow of moisture or external ions into the porous low-dielectric layer 130 and diffusion of metals from the metal interconnection 170. According to embodiments of the inventive concept, the capping layer 200 may include at least one material selected from the group consisting of a SiN layer, a SiCN layer, a BN layer, and a BCN layer.

Furthermore, the formation of the capping layer 200 and the moisture removing process may be performed in-situ.

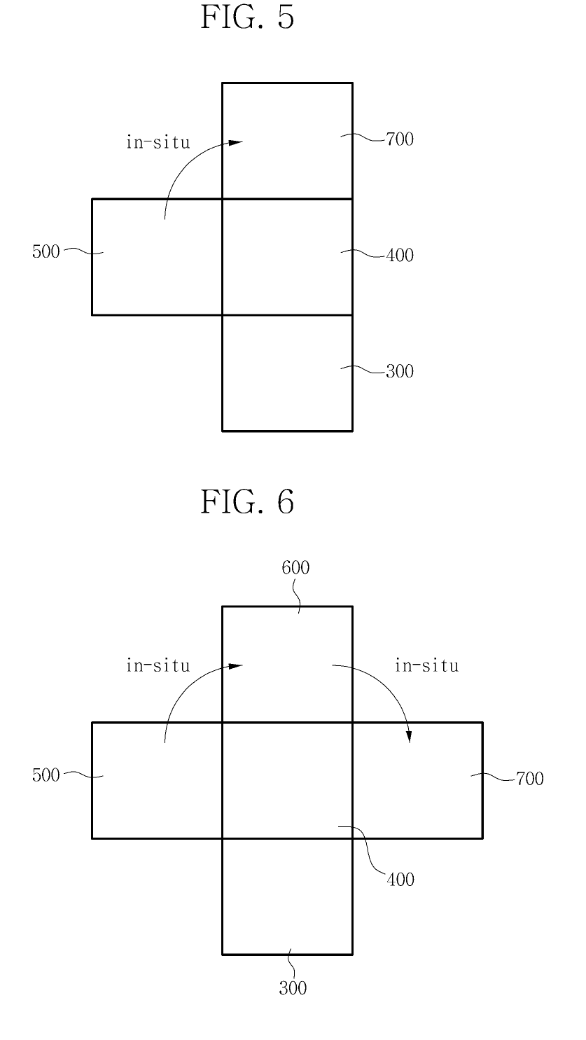

FIGS. 5 and 6 are schematic views of an apparatus for manufacturing a semiconductor device, by which the moisture removing process of the inventive concept may be performed.

A substrate may be loaded into the apparatus for manufacturing the semiconductor device according to embodiments of the inventive concept by a loadlock chamber 300. A transfer module 400 may be disposed adjacent to one side of the loadlock chamber 300. Process chambers 500, 600, and 700 may be arranged at regular intervals around the transfer module 400. Thereafter, the substrate disposed in the loadlock chamber 300 may be transferred to each of the process chambers 500, 600, and 700 by the transfer module 400, or the substrate disposed in each of the process chambers 500, 600, and 700 may be transferred to the loadlock chamber 300 by the transfer module 400.

The apparatus for manufacturing the semiconductor device according to embodiments of the inventive concept may include a UV irradiation chamber 500 and a capping layer deposition chamber 700. The UV irradiation chamber 500 may be configured to irradiate UV light with a wavelength of about 260 to 450 nm. The capping layer deposition chamber 700 may be disposed adjacent to the UV irradiation chamber 500 and include a capping layer depositor.

The UV irradiation chamber 500 may include an apparatus configured to irradiate UV light to the top surface of the porous low-dielectric layer 130 and the top surface of the metal interconnection 170. The light energy irradiation apparatus may be a UV lamp configured to irradiate UV light having a wavelength of about 260 to 450 nm. According to other embodiments of the inventive concept, the light energy irradiation apparatus may include a wide bandgap UV lamp 190 and a UV filter 195 configured to selectively transmit UV light having a wavelength of about 260 to 450 nm.

The capping layer deposition chamber 700 may include a capping layer deposition unit. The capping layer 200 may include at least one material selected from the group consisting of a SiN layer, a SiCN layer, a BN layer, and a BCN layer. The capping layer deposition chamber 700 may perform one of a plasma-enhanced CVD (PECVD) process, a thermal CVD process, a CVD process, a spin coating process, a sputtering deposition process, a PVD process, and an ALD process.

The capping layer deposition chamber 700 may further include a plasma generator. In this case, a plasma process and a capping layer deposition process may be sequentially performed in the capping layer deposition chamber 700. The plasma process may be performed in an atmosphere containing NH₃, H₂, He, N₂, Ar, or a mixture thereof.

Processes in the UV irradiation chamber 500 and the capping layer deposition chamber 700 may be performed in-situ without breaking a vacuum state to prevent additional moisture absorption after absorbed moisture is removed using UV irradiation.

According to other embodiments of the inventive concept, an apparatus for manufacturing a semiconductor device may include an additional plasma process chamber 600, which is interposed between the UV irradiation chamber 500 and the capping layer deposition chamber 700 and includes a plasma generator. As described above, the UV irradiation chamber 500 may be used to perform an absorbed-moisture removing process, while the plasma process chamber 600 may be used to perform a plasma process. In this case, the plasma process may be performed in an atmosphere containing NH₃, H₂, He, N₂, Ar, or a mixture thereof. Also, the capping layer deposition chamber 700 may include a capping layer depositor to enable formation of the capping layer 200. Similarly, all processes in the LTV irradiation chamber 500, the plasma process chamber 600, and the capping layer deposition chamber 700 may be performed in-situ.

When the plasma process chamber 600 including the plasma generator is interposed between the UV irradiation chamber 500 and the capping layer deposition chamber 700, the capping layer deposition chamber 700 may not include a plasma generator.

A door (not shown) configured to open and close off an entrance (not shown) through which a substrate is loaded and unloaded may be installed among the loadlock chamber 300, the transfer module 400, and each of the process chambers 500, 600, and 700. The door may control the flow of gases and impurities among the loadlock chamber 300, the transfer module 400, and the respective process chambers 500, 600, and 700 and maintain pressures among the respective chambers. The loadlock chamber 300 may be maintained in a low-vacuum state, and the transfer module 400, the UV irradiation chamber 500, the plasma process chamber 600, and the capping layer deposition chamber 700 may be maintained in a high-vacuum state.

When the substrate is loaded from the loadlock chamber 300 into the transfer module 400 and the door is opened, a whirlpool may occur. To prevent the occurrence of the whirlpool, after the substrate is mounted in the transfer module 400, the transfer module 400, the UV irradiation chamber 500, the plasma process chamber 600, and the capping layer deposition chamber 700, which are in a high-vacuum state, may be pumped. Due to the high-vacuum state of the transfer module 400 and the respective process chambers 500, 600, and 700, even if the door between the transfer module 400 and each of the process chambers 500, 600, and 700 is opened, required processes may be performed in-situ without breaking the vacuum state.

The present inventive concept is not limited to the above-described embodiments and may be modified in other various forms within the spirit and scope of the inventive concept.

According to still other embodiments of the inventive concept, a porous low-dielectric layer may be formed on the substrate. In this case, the porous low-dielectric layer may be a planarization layer without openings. A metal layer may be formed on the porous low-dielectric layer. A metal interconnection may include Cu or a Cu alloy. The metal layer may be patterned to form the metal interconnection. To remove the absorbed moisture from the porous low-dielectric layer, UV light having a wavelength of about 260 to 450 nm may be irradiated to the porous low-dielectric layer. Subsequently, to prevent additional absorption of moisture, a capping layer may be formed on lateral and top surfaces of the metal interconnection to cover the porous low-dielectric layer. In this case, the UV irradiation and the capping layer deposition process may be performed in-situ without breaking a vacuum state. Furthermore, before the capping layer deposition process, a process of processing the surfaces of the metal interconnection and the porous low-dielectric layer using plasma may be performed.

According to a method of the embodiments, after a metal layer is polished using a CMP process, all kinds of moisture may be effectively removed using one absorbed-moisture removing process from a porous low-dielectric layer exposed to the air. In this case, H₂O moisture may be attached to pores of the porous low-dielectric layer. Also, —OH or —H moisture may be absorbed into the porous low-dielectric layer. Therefore, by irradiating predetermined light energy, for example, UV light having a predetermined wavelength, to top surfaces of the porous low-dielectric layer and the metal interconnection, various kinds of moisture may be removed. The porous low-dielectric layer from which the absorbed moisture is removed may maintain a low dielectric constant, thereby improving the electrical properties of the semiconductor device.

Furthermore, according to an apparatus of the embodiments, after absorbed moisture is removed, a plasma process and a capping layer deposition process may be performed in-situ, thereby effectively preventing additional absorption of moisture in the porous low-dielectric layer.

The foregoing is descriptive of embodiments and is not to be construed as limiting thereof. Although some embodiments have been described, those skilled in the art will readily appreciate that many modifications are possible in embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments described, and that modifications to the described embodiments, as well as other embodiments, are intended to be included within the scope of the appended claims.

1. A method of manufacturing a semiconductor device, comprising:
forming a porous low-dielectric layer on a substrate;
forming a metal interconnection on the substrate having the porous low-dielectric layer;
irradiating ultraviolet (UV) light having a wavelength of 260 to 450 nm to the porous low-dielectric layer; and
forming a capping layer on the substrate having the porous low-dielectric layer and the metal interconnection.

2. The method of claim 1, wherein the porous low-dielectric layer comprises a material selected from the group consisting of a SiOCH layer, a SiOC layer, and a SiOF layer.

3. The method of claim 1, wherein the porous low-dielectric layer has a dielectric constant of about 1 to 2.5.

4. The method of claim 1, wherein the capping layer comprises a material selected from the group consisting of a SiN layer, a SiCN layer, a BN layer, a BCN layer, and a mixture thereof.

5. The method of claim 1, wherein the metal interconnection comprises copper (Cu) or a Cu alloy.

6. The method of claim 1, wherein irradiating UV light to the porous low-dielectric layer and forming the capping layer on the substrate are performed in-situ.

7. The method of claim 1, wherein forming the porous low-dielectric layer comprises:
forming a low-dielectric layer including a pore generator (porogen) on the substrate; and
removing the porogen.

8. The method of claim 7, wherein removing the porogen is performed using at least one of a UV irradiation process, an electronic beam (e-beam) irradiation process, and an annealing process.

9. The method of claim 1, wherein forming the metal interconnection comprises:
etching a portion of the porous low-dielectric layer to form an opening;
forming a barrier layer to cover the opening and the porous low-dielectric layer;
forming a metal layer on the barrier layer to fill the opening; and
polishing a portion of the metal layer and the barrier layer formed on the porous low-dielectric layer to expose a top surface of the porous low-dielectric layer.

10. The method of claim 9, wherein polishing the portion of the metal layer and the barrier layer formed on the porous low-dielectric layer comprises performing a chemical mechanical polishing (CMP) process using the top surface of the porous low-dielectric layer as an etch stopper.

11. The method of claim 10, wherein the barrier layer comprises at least one material selected from the group consisting of titanium (Ti), tantalum (Ta), tungsten (W), and a nitride thereof.

12. The method of claim 1, further comprising, after irradiating UV light to the porous low-dielectric layer and before forming the capping layer, processing the porous low-dielectric layer and the metal interconnection using plasma, wherein irradiating UV light to the porous low-dielectric layer, processing the porous low-dielectric layer and the metal interconnection using plasma, and forming the capping layer on the substrate are performed in-situ.

13. The method of claim 12, wherein processing the porous low-dielectric layer and the metal interconnection using plasma is performed in an atmosphere containing at least one of ammonia (NH₃), hydrogen (H₂), helium (He), nitrogen (N₂), argon (Ar), and a mixture thereof.

14.-25. (canceled)

26. A method of manufacturing a semiconductor device, comprising:
forming a porous low-dielectric layer on a substrate;
forming a metal interconnection on the substrate having the porous low-dielectric layer;
irradiating ultraviolet (UV) light having a wavelength of 260 to 450 nm to the porous low-dielectric layer;
forming a capping layer on the substrate having the porous low-dielectric layer and the metal interconnection; and
wherein irradiating UV light to the porous low-dielectric layer and forming the capping layer on the substrate are performed in-situ.

27. The method of claim 26, further comprising, after irradiating UV light to the porous low-dielectric layer and before forming the capping layer, processing the porous low-dielectric layer and the metal interconnection using plasma,

28. The method of claim 27, wherein irradiating UV light to the porous low-dielectric layer, processing the porous low-dielectric layer and the metal interconnection using plasma, and forming the capping layer on the substrate are performed in-situ.

29. The method of claim 26, wherein forming the capping layer on the substrate comprises performing one process selected from the group consisting of a plasma-enhanced chemical vapor deposition (PECVD) process, a thermal CVD process, a CVD process, a spin coating process, a sputtering deposition process, a physical vapor deposition (PVD) process, and an atomic layer deposition (ALD) process.

30. The method of claim 26, wherein irradiating ultraviolet (UV) light to the porous low-dielectric layer is performed using at least one of;
a UV lamp configured to irradiate UV light having a wavelength of about 260 to 450 nm; and
a wide-bandgap UV lamp and a UV filter configured to selectively transmit UV light having a wavelength of about 260 to 450 nm.
